(19) United States
(12) Patent Application Publication
(10) Pub. No.: US 2019/0035673 A1
(43) Pub. Date: Jan. 31, 2019

(54) FLOWABLE DIELECTRICS FROM VAPOR PHASE PRECURSORS

(71) Applicant: Intel Corporation, Santa Clara, CA (US)

(72) Inventors: Ebony L. Mays, Hillsboro, OR (US); Jeanne L. Luce, Hillsboro, OR (US); Elizabeth Mallon, Hillsboro, OR (US)

(21) Appl. No.: 16/077,555

(22) PCT Filed: Mar. 31, 2016
(86) PCT No.: PCT/US2016/025420

§ 371 Date: Aug. 13, 2018

(51) Int. Cl. H01L 21/762; H01L 21/02; H01L 29/78

(52) U.S. Cl. CPC H01L 21/76224; H01L 21/02211; H01L 29/7851; H01L 21/02356; H01L 21/0228

(57) ABSTRACT

An embodiment includes a semiconductor apparatus comprising: a trench with an aspect ratio of at least 7:1 (height:width); and a dielectric included in the trench; wherein the dielectric: (a) includes carbon and at least one of silicon nitride and silicon carbide, and (b) does not include an oxide. Other embodiments are described herein.

### TECHNICAL FIELD

Embodiments of the invention are in the field of semiconductor devices and, in particular, dielectric materials.

### BACKGROUND

As described in U.S. Pat. No. 6,876,053 (assigned to Intel Corp. of Santa Clara, Calif., USA), semiconductor integrated circuits are formed by chemically and physically forming circuit components in and on a semiconductor substrate. These circuit components are generally conductive (e.g., for conductor and resistor fabrication) and may be of different conductivity types (e.g., for transistor and diode fabrication). Thus, when forming such circuit components, they may need to be electrically isolated from one another, wherein electrical communication between the isolated circuit components is achieved through discrete electrical traces.

Various techniques have been developed for electrically isolating integrated circuit components formed in the semiconductor substrate. One such technique is known as trench isolation. The trench isolation technique involves forming a channel or trench in the semiconductor substrate, usually by etching techniques well known in the art. The trench is formed to surround the circuit components to be isolated and filled with a dielectric material, thereby electrically isolating the circuit components.

### BRIEF DESCRIPTION OF THE DRAWINGS

Features and advantages of embodiments of the present invention will become apparent from the appended claims, the following detailed description of one or more example embodiments, and the corresponding figures. Where considered appropriate, reference labels have been repeated among the figures to indicate corresponding or analogous elements.

FIG. 1 includes a process 100 in an embodiment.

FIG. 2 includes a FinFET with shallow trench isolation in an embodiment.

FIG. 3 includes a process in an embodiment.

FIGS. 4, 5, 6 include systems that include embodiments of dielectrics described herein.

### DETAILED DESCRIPTION

Reference will now be made to the drawings wherein like structures may be provided with like suffix reference designations. In order to show the structures of various embodiments more clearly, the drawings included herein are diagrammatic representations of semiconductor/circuit structures. Thus, the actual appearance of the fabricated integrated circuit structures, for example in a photomicrograph, may appear different while still incorporating the claimed structures of the illustrated embodiments. Moreover, the drawings may only show the structures useful to understand the illustrated embodiments. Additional structures known in the art may not have been included to maintain the clarity of the drawings. For example, not every layer of a semiconductor device is necessarily shown. “An embodiment”, “various embodiments” and the like indicate embodiment(s) so described may include particular features, structures, or characteristics, but not every embodiment necessarily includes the particular features, structures, or characteristics. Some embodiments may have some, all, or none of the features described for other embodiments. “First”, “second”, “third” and the like describe a common object and indicate different instances of like objects are being referred to. Such adjectives do not imply objects so described must be in a given sequence, either temporally, spatially, in ranking, or in any other manner. “Connected” may indicate elements are in direct physical or electrical contact with each other and “coupled” may indicate elements co-operate or interact with each other, but they may or may not be in direct physical or electrical contact.

As mentioned above, dielectric materials may be used to “gapfill” a trench to provide electrical isolation between portions of an apparatus. Some such dielectrics are “flowable” in that they may be formed in a state whereby they flow before eventually being cured into ceramic form. Flowable dielectric materials can be critical to providing dielectric gapfill/isolation in patterned features, such as trenches, with high aspect ratios (AR) and small critical dimensions (CD). An example of a high AR is 5:1, 6:1, 7:1, 8:1 or higher and an example of small CD is 20, 18, 16, 14, 12, 10 nm or less.

As used herein, AR is defined by the height (measured vertically and orthogonally to main plain of substrate):width (measured horizontally and parallel to main plain of substrate) ratio of a structure (e.g., trench). As used herein, CD is defined by dimensions of the smallest geometrical features (e.g., width of interconnect line, contacts, trenches) that can be formed during semiconductor device manufacturing. As used herein, a trench is a geometric feature formed in a material, such as a substrate or interlayer dielectric (ILD).

Applicant has determined several issues unique to conventional isolation techniques. First, Applicant determined that in high AR/low CD features flowable materials uniquely fill without seams or voids in contrast to CVD/ALD deposited materials. In other words, conformal techniques such as CVD/ALD close the width of a higher AR trench at the same rate or faster than they close the height, thereby producing a seam or void. Second, Applicant determined that as scaling continues (CD lowers), patterning schemes rely more heavily on high etch selectivity between materials to form patterns. Third, Applicant determined a flowable dielectric may be formed after other features have been formed. As a result, the dielectric may be restricted to a temperature range that allows the dielectric to flow and be cured without damaging other portions of a device that have already been formed (e.g., metal contacts). Such instances require the gapfill dielectric to meet lower process thermal budgets (e.g., ≤400 C). Fourth, Applicant determined that a dielectric must not only comply with thermal budgets but also exhibit compatibility with metals (e.g., no metal oxidation or electrical performance shift) while still providing good electrical leakage properties.

Applicant has determined various embodiments that address the issues addressed above. An embodiment includes an etch-resistant and mechanically robust flowable silicon nitride film for use in selective etch patterning schemes. Such an embodiment includes a flowable dielectric (e.g., flowable silicon nitride, flowable silicon carbide, flowable doped silicon nitride, flowable doped silicon carbide pre-ceramics) formed from oligomerized/polymerized vapor phase precursors. The dielectric may be: (a) used in a trench with an AR greater than 5:1 and with a CD less than 15 nm, (b) formed at less than 400 degrees C., and (c) exhibit compatibility with metals, are mechanically robust, and exhibit etch resistance—all while providing good electrical leakage.

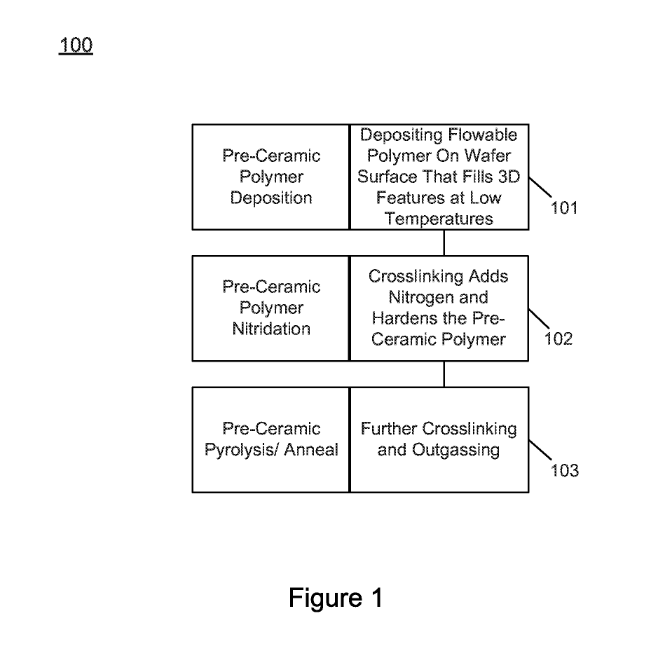

FIG. 1 includes a process 100 in an embodiment.

In block 101 a silazane compound is used to synthesize oligomeric and polymeric silicon nitride pre-ceramic compounds. Precursor selection aids in propagating polymerization and crosslinking reactions while limiting shrinkage due to outgassing of unbound precursor and reaction byproducts of the final dielectric (which can lead to voids) in subsequent processing steps. An embodiment concerns selection of a precursor that results in low residual unbound precursor and outgassing by-products in the final dielectric. Limiting the unbound precursor and outgassing by-products (e.g., hydrogen) is important to minimizing shrinkage of the final film and minimizing the amount of dielectric lost during downstream processes (i.e. later etch processes). And as mentioned above, minimizing shrinking helps minimize voiding. For the vapor phase deposition of block 101, an embodiment utilizes precursors that contain, for example, silicon and nitrogen (but with minimal unwanted elements). Furthermore, embodiments use precursors that can produce flowable films from vapor phase precursors. Embodiments include precursors such as, for example, highly reactive Trisilylamine (TSA) and cyclodisilazane compounds. Other embodiments use, without limitation, vapor phase precursors such as Bis(tertiary-butyl-amino)silane (BTBAS), Tris(isopropylamino)silane (TIPAS), Bis(diethylamino)ethylsilane (BDEAES), Bis(diethylamino)silane (BDEAS), and Tris(ethylamino)silane (TEAS), polycarbosilanes, polyvinylsilanes, cyclical compounds, and mixtures thereof. Further, embodiments are not limited to dehydrocondensation reactions. In block 101 the starting precursor compound (e.g., TSA) reacts to produce oligomers and/or polysilazane polymer through dehydrocondensation reactions involving Si—H and N—H groups. In an embodiment ammonia and ammonia radicals are used to catalyze the oligomerization/polymerization reaction. In block 101, an embodiment generates polymer chains at the wafer surface that are short enough to condense, flow, and fill high AR (e.g., >5:1) features (e.g., trenches formed in a semiconductor substrate). Concomitantly, the polymer chains are long enough to build a high molecular weight polymer. This is important because a high degree of polymerization helps minimize volatilization of the reacting compound, minimize shrinkage, increase density, and increase final ceramic yield in block 102.

In blocks 101 and 102, the pre-ceramic polymer is highly reactive with oxygen and moisture. Therefore, during blocks 101 and 102 the material is kept under vacuum conditions and/or transported with nitrogen purge until it is stabilized.

In block 102 crosslinking and addition of nitrogen (i.e., nitridation) through the thickness of the film achieves a uniform, stoichiometric silicon nitride film (although the end product is non-stoichiometric in some embodiments). In block 102 volatilization of low molecular weight oligomers and high shrinkage can lead to voiding in the features. However, embodiments use additives such as pyridine, pyridine adducts, methyl substituted piperidine, alkylamines, acids, ammonia vapor, hydrazine vapor, potassium hydride, and oxygen to catalyze crosslinking and densification of films at low temperature (e.g., <500 degrees C.). In block 102 reactive, high pressure (≥1 atm) thermal processing (25-500° C.) is important to minimizing volatilization and providing a high degree of crosslinking. Stabilization of the polymer through crosslinking of terminal hydrides and amines is required in some embodiments. Without the critical conditions addressed above, volatile precursor/reactant species can evolve from the feature causing shrinkage and voiding. In this block 102 deposition/cure cycles can be used in some cases to fill voided features.

In block 103 high energy pyrolytic/anneal processing creates a hardened, thermodynamically stable final dielectric film. The processing may use, in some embodiments, one or more of reactive UV, thermal, energetic plasma, and implant processing. Block 103 helps drive final crosslinking and outgassing of crosslinking products such as hydrogen, oxygen, and carbon. Reactive processes in nitrogen and ammonia are used in some embodiments to minimize defect densities that cause poor etch resistance and electrical properties.

In an embodiment the flowable dielectric (e.g., end product of block 101) is not stoichiometric. For example, instead of pure Si₃N₄, an embodiment includes a flowable silicon oxynitride film (made from TSA precursor), after anneal: <1% carbon, 15-25% nitrogen, <20% oxygen, >45% silicon, and <15% hydrogen. However, another embodiment includes <1% carbon, >20% nitrogen, <5% oxygen, >55% silicon, and <15% hydrogen.

In an embodiment carbon doping is employed by use of mixtures of carbon containing vapor phase precursors such as, for example, polycarbosilane, polyvinlsilanes, and mixtures thereof with each other and the precursors (e.g., TSA) noted above.

Annealing helps drive down hydrogen content, which is active and conducive to etching in subsequent etching steps (which can lead to poor etch resistance). Performing an anneal also reduces terminal hydrogen and amine concentrations (both of which increase the reactivity of the film, thereby increasing the etch rate of the material in common etchants).

Some embodiments include enough oxygen so the oxygen functions as a crosslinking agent in, for example, a silicon nitride film. The oxygen crosslinking reduces the concentration of terminal hydrogen and amines, thereby reducing the etch rate of the film. However, other embodiments use nitrogen and/or ammonia which decrease the amount of oxygen.

Regarding oxygen, oxygen may come from intentional addition or as a contaminant if present when the precursors are most reactive. Low temperature anneals may not rid the final materials of oxygen. Thus, some embodiments may retain low oxygen content in their final form. In some embodiments high oxygen content is undesirable for certain etch chemistries but desirable in others. The control of oxygen content goes towards etch selectivity.

Please note blocks 101, 102, 103 need not be discrete. For example, blocks 101 and 102 could be combined such that elements used in block 102 are deposited during performance of block 101. Similarly, blocks 101 and 102 may be performed in a cyclical fashion, followed by block 103 after a number of cycles have occurred.

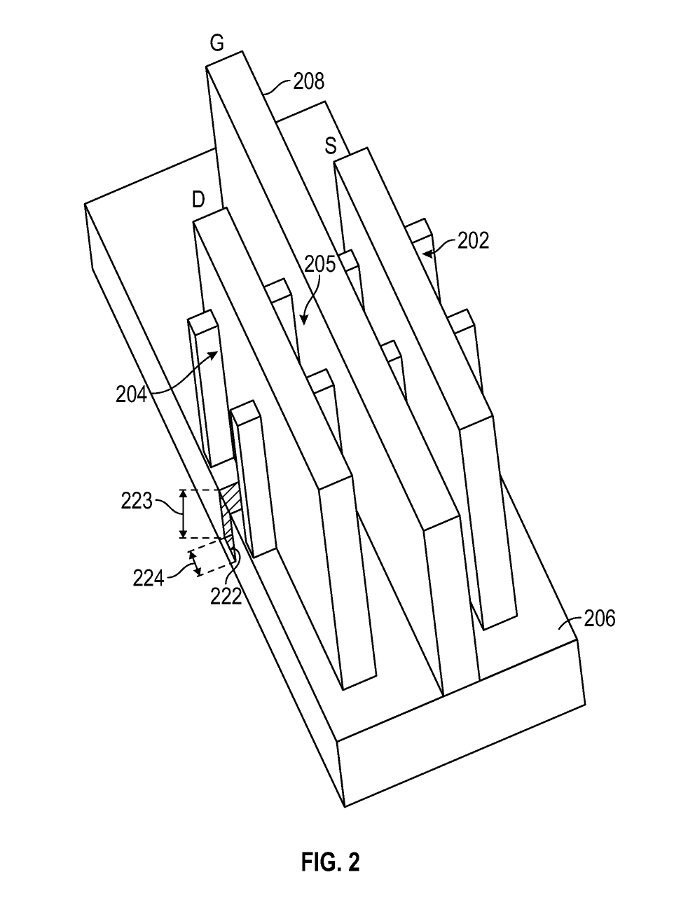

FIG. 2 illustrates several fins that collectively help form a poly gate Metal Oxide Semiconductor Field Effect Transistor (MOSFET). A FinFET is a transistor built around a thin strip of semiconductor material (referred to as the “fin”). As shown in FIG. 2, the transistor includes the standard field effect transistor (FET) nodes/components: a gate, a gate dielectric, a source region 202, and a drain region 204. The conductive channel 205 of the device resides on the outer sides of the fin beneath the gate dielectric (which is obscured by gate structure 208). Specifically, current runs along both “sidewalls” of the fin as well as along the top side of the fin. Because the conductive channel essentially resides along the three different outer, planar regions of the fin, such a FinFET is typically referred to as a “tri-gate” FinFET. Other types of FinFETs exist (such as “double-gate” FinFETs in which the conductive channel principally resides only along both sidewalls of the fin and not along the top side of the fin). The source region 202 and the drain region 204 may be implanted with either a p-type material, such as boron, to form a pMOS (p-channel Metal Oxide Semiconductor) transistor or an n-type material, usually phosphorous and/or arsenic, to form an nMOS (n-channel Metal Oxide Semiconductor) transistor. A gate structure 208 spans a region of the semiconductor substrate 206 between the source region 202 and the drain region 204. Fins may be isolated from one another with an isolation structure 222 (i.e., a dielectric-filled trench) extending into the semiconductor substrate 206. The trench may include an AR of 5:1, 6:1, 7:1, 8:1 (height 223:width 224) or higher and the isolation structure may include a flowable dielectric described herein. The use of the precursors described herein allow for a flowable dielectric that can gapfill the trench (without or with few seams or voids) despite the trench having such a high AR. This would not be possible with CVD/ALD.

While a FinFET transistor is shown, a conventional planar transistor would also be available without changing the concept of trench isolation with a high AR trench being best suited by a flowable dielectric described herein.

While gapfilling trenches within a substrate has been discussed at length herein, embodiments are not so limited and flowable dielectrics described herein may be used in various forms, such as trenches formed within metallization layers, as under fill material between a semiconductor die and a carrier substrate, slit fill for vertical NAND, DRAM buried bit lines, and the like.

While many embodiments herein disclose the dielectric directly contacting trench walls, other embodiments may use a thin conformal intermediate layer (e.g., barrier layer), such as a conformal layer of silicon dioxide, in the isolation structure prior to depositing any of the various dielectric materials described herein.

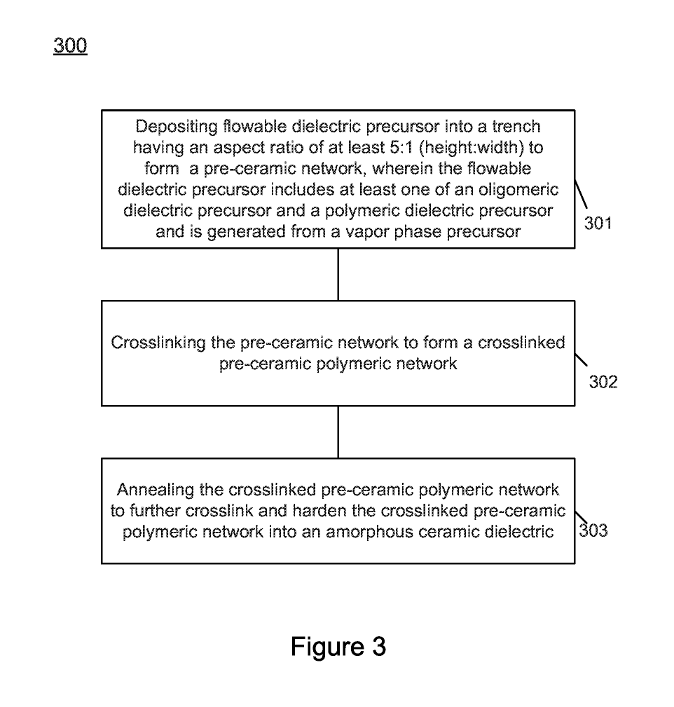

FIG. 3 includes a process in an embodiment. Block 301 includes depositing flowable dielectric precursor into a trench having an aspect ratio of at least 5:1 (height:width) to form a pre-ceramic network. The flowable dielectric precursor includes at least one of an oligomeric dielectric precursor and a polymeric dielectric precursor and is generated from a vapor phase precursor. The vapor phase precursor may include a silazane compound (e.g. TSA). Block 101 may be conducted at less than 500 degrees C. and under vacuum. Block 302 includes crosslinking the pre-ceramic network to form a crosslinked pre-ceramic polymeric network (at less than 500 degrees C. and under the same vacuum from block 301) while the pre-ceramic network is exposed to nitrogen. Block 303 includes annealing the crosslinked pre-ceramic polymeric network (at less than 500 degrees C.) to further crosslink and harden the crosslinked pre-ceramic polymeric network into an amorphous ceramic dielectric.

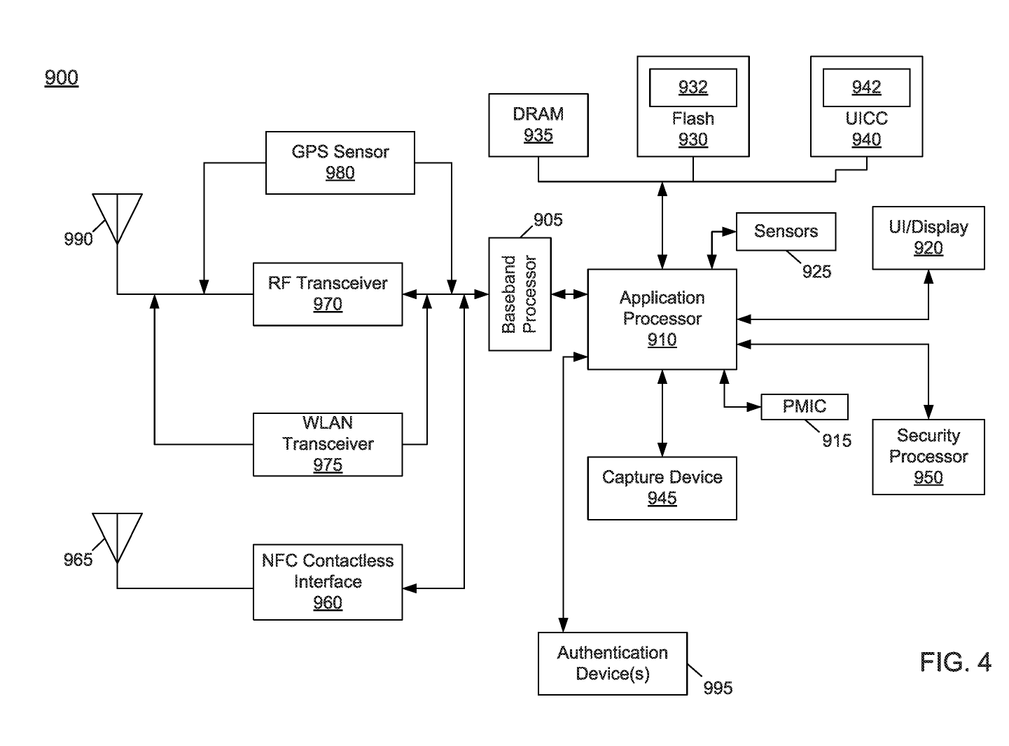

FIGS. 4, 5, 6 each include a system that may include any of the above described embodiments. FIGS. 4, 5, 6 include block diagrams of systems 900, 1000, 1300 in accordance with embodiments. Each of those systems may include hundreds or thousands of the above described isolation structures and be critical to functions in those systems. For example, the dielectrics may be used in memory cells that are included in, for example, elements 910, 930, 1070, 1032, 1090, 1310, 1340, 1380, and the like. Systems 900, 1000, 1300 may be included in, for example, a mobile computing node such as a cellular phone, smartphone, tablet, Ultrabook®, notebook, laptop, personal digital assistant, and mobile processor based platform. The stability (lack of seams or voids) accumulates when the dielectrics (e.g., included in memory cells) are deployed in mass and provides significant performance advantages (e.g., reliability at lower CDs) to such computing nodes.

Referring now to FIG. 4, shown is a block diagram of an example system with which embodiments can be used. As seen, system 900 may be a smartphone or other wireless communicator or any other IoT device. A baseband processor 905 is configured to perform various signal processing with regard to communication signals to be transmitted from or received by the system. In turn, baseband processor 905 is coupled to an application processor 910, which may be a main CPU of the system to execute an OS and other system software, in addition to user applications such as many well-known social media and multimedia apps. Application processor 910 may further be configured to perform a variety of other computing operations for the device.

In turn, application processor 910 can couple to a user interface/display 920, e.g., a touch screen display. In addition, application processor 910 may couple to a memory system including a non-volatile memory, namely a flash memory 930 and a system memory, namely a DRAM 935. In some embodiments, flash memory 930 may include a secure portion 932 in which secrets and other sensitive information may be stored. As further seen, application processor 910 also couples to a capture device 945 such as one or more image capture devices that can record video and/or still images.

A universal integrated circuit card (UICC) 940 comprises a subscriber identity module, which in some embodiments includes a secure storage 942 to store secure user information. System 900 may further include a security processor 950 that may couple to application processor 910. A plurality of sensors 925, including one or more multi-axis accelerometers may couple to application processor 910 to enable input of a variety of sensed information such as motion and other environmental information. In addition, one or more authentication devices 995 may be used to receive, e.g., user biometric input for use in authentication operations.

As further illustrated, a near field communication (NFC) contactless interface 960 is provided that communicates in a NFC near field via an NFC antenna 965. While separate antennae are shown, understand that in some implementations one antenna or a different set of antennae may be provided to enable various wireless functionalities.

A power management integrated circuit (PMIC) 915 couples to application processor 910 to perform platform level power management. To this end, PMIC 915 may issue power management requests to application processor 910 to enter certain low power states as desired. Furthermore, based on platform constraints, PMIC 915 may also control the power level of other components of system 900.

To enable communications to be transmitted and received such as in one or more IoT networks, various circuitries may be coupled between baseband processor 905 and an antenna 990. Specifically, a radio frequency (RF) transceiver 970 and a wireless local area network (WLAN) transceiver 975 may be present. In general, RF transceiver 970 may be used to receive and transmit wireless data and calls according to a given wireless communication protocol such as 3G or 4G wireless communication protocol such as in accordance with a code division multiple access (CDMA), global system for mobile communication (GSM), long term evolution (LTE) or other protocol. In addition a GPS sensor 980 may be present, with location information being provided to security processor 950 for use as described herein when context information is to be used in a pairing process. Other wireless communications such as receipt or transmission of radio signals, e.g., AM/FM and other signals may also be provided. In addition, via WLAN transceiver 975, local wireless communications, such as according to a Bluetooth™ or IEEE 802.11 standard can also be realized.

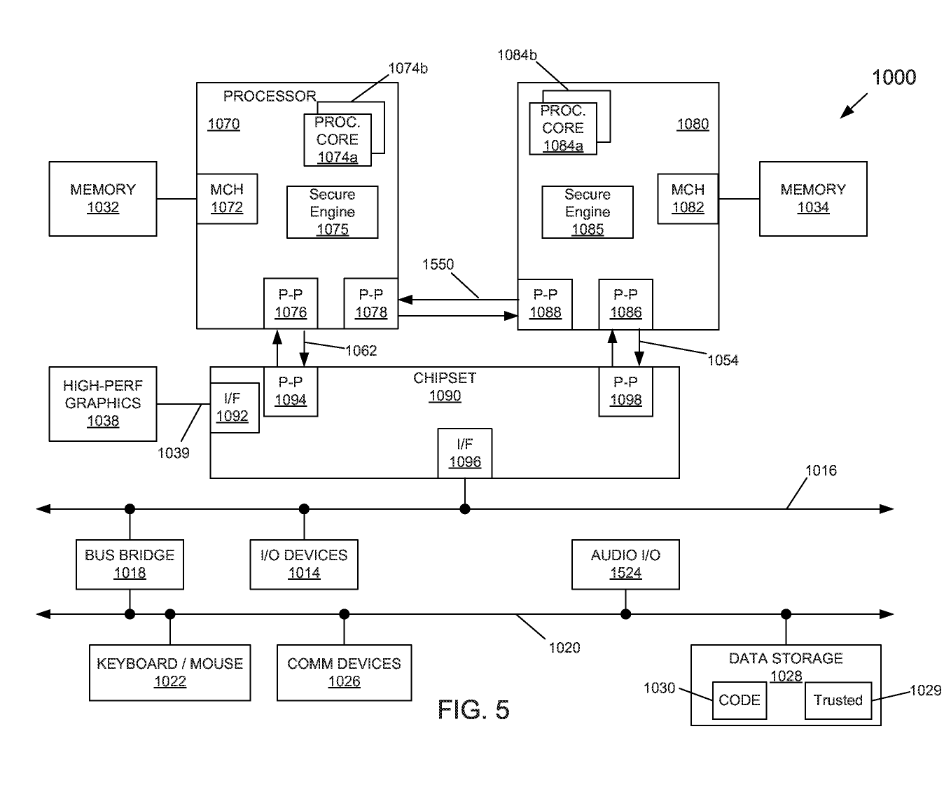

Referring now to FIG. 5, shown is a block diagram of a system in accordance with another embodiment of the present invention. Multiprocessor system 1000 is a point-to-point interconnect system such as a server system, and includes a first processor 1070 and a second processor 1080 coupled via a point-to-point interconnect 1050. Each of processors 1070 and 1080 may be multicore processors such as SoCs, including first and second processor cores (i.e., processor cores 1074a and 1074b and processor cores 1084a and 1084b), although potentially many more cores may be present in the processors. In addition, processors 1070 and 1080 each may include a secure engine 1075 and 1085 to perform security operations such as key management, attestations, IoT network onboarding or so forth.

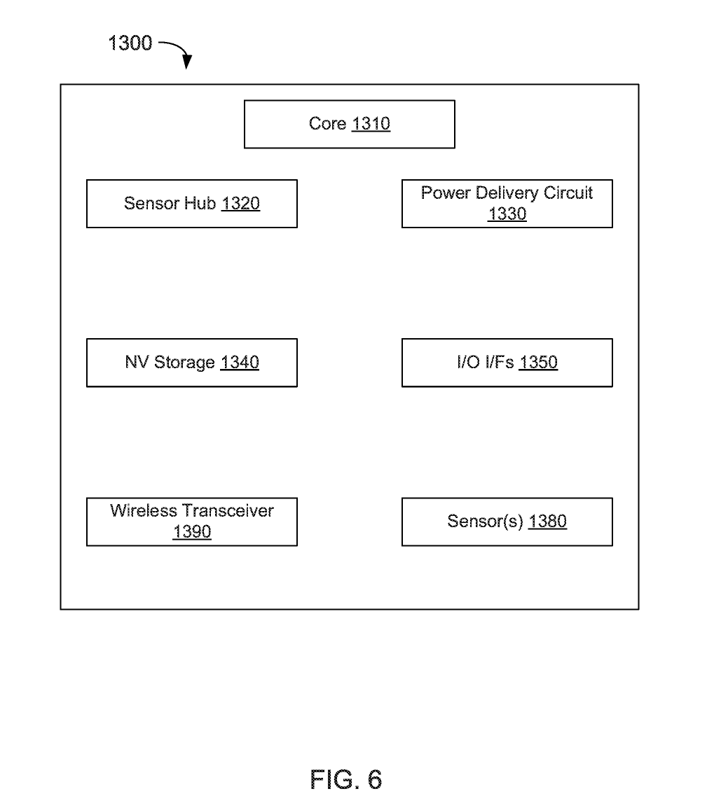

First processor 1070 further includes a memory controller hub (MCH) 1072 and point-to-point (P-P) interfaces 1076 and 1078. Similarly, second processor 1080 includes a MCH 1082 and P-P interfaces 1086 and 1088. MCH's 1072 and 1082 couple the processors to respective memories, namely a memory 1032 and a memory 1034, which may be portions of main memory (e.g., a DRAM) locally attached to the respective processors. First processor 1070 and second processor 1080 may be coupled to a chipset 1090 via P-P interconnects 1052 and 1054, respectively. As shown in FIG. 6, chipset 1090 includes P-P interfaces 1094 and 1098.

Furthermore, chipset 1090 includes an interface 1092 to couple chipset 1090 with a high performance graphics engine 1038, by a P-P interconnect 1039. In turn, chipset 1090 may be coupled to a first bus 1016 via an interface 1096. Various input/output (I/O) devices 1014 may be coupled to first bus 1016, along with a bus bridge 1018 which couples first bus 1016 to a second bus 1020. Various devices may be coupled to second bus 1020 including, for example, a keyboard/mouse 1022, communication devices 1026 and a data storage unit 1028 such as a non-volatile storage or other mass storage device. As seen, data storage unit 1028 may include code 1030, in one embodiment. As further seen, data storage unit 1028 also includes a trusted storage 1029 to store sensitive information to be protected. Further, an audio I/O 1024 may be coupled to second bus 1020.

Embodiments may be used in environments where Internet of Things (IoT) devices may include wearable devices or other small form factor IoT devices. Referring now to FIG. 6, shown is a block diagram of a wearable module 1300 in accordance with another embodiment. In one particular implementation, module 1300 may be an Intel® Curie™ module that includes multiple components adapted within a single small module that can be implemented as all or part of a wearable device. As seen, module 1300 includes a core 1310 (of course in other embodiments more than one core may be present). Such core may be a relatively low complexity in-order core, such as based on an Intel Architecture® Quark™ design. In some embodiments, core 1310 may implement a TEE as described herein. Core 1310 couples to various components including a sensor hub 1320, which may be configured to interact with a plurality of sensors 1380, such as one or more biometric, motion environmental or other sensors. A power delivery circuit 1330 is present, along with a non-volatile storage 1340. In an embodiment, this circuit may include a rechargeable battery and a recharging circuit, which may in one embodiment receive charging power wirelessly. One or more input/output (IO) interfaces 1350, such as one or more interfaces compatible with one or more of USB/SPI/I2C/GPIO protocols, may be present. In addition, a wireless transceiver 1390, which may be a Bluetooth™ low energy or other short-range wireless transceiver is present to enable wireless communications as described herein. Understand that in different implementations a wearable module can take many other forms. Wearable and/or IoT devices have, in comparison with a typical general purpose CPU or a GPU, a small form factor, low power requirements, limited instruction sets, relatively slow computation throughput, or any of the above.

Various embodiments include a semiconductive substrate. Such a substrate may be a bulk semiconductive material this is part of a wafer. In an embodiment, the semiconductive substrate is a bulk semiconductive material as part of a chip that has been singulated from a wafer. In an embodiment, the semiconductive substrate is a semiconductive material that is formed above an insulator such as a semiconductor on insulator (SOI) substrate. In an embodiment, the semiconductive substrate is a prominent structure such as a fin that extends above a bulk semiconductive material.

The following examples pertain to further embodiments.

Example 1 includes a semiconductor apparatus comprising: a trench with an aspect ratio of at least 7:1 (height:width); and a dielectric included in the trench; wherein the dielectric: (a) includes carbon and at least one of silicon nitride and silicon carbide, and (b) does not include an oxide.

The AR and CD described herein are critical dimensions as they cooperate to preclude traditional means, such as CVD (non-flowable) and ALD, as options.

In example 2 the subject matter of the Example 1 can optionally include wherein the dielectric includes a carbon-carbon double bond.

A C═C bond may be indicative of polyvinylsilazane precursors being used in block 101 of FIG. 1.

In example 3 the subject matter of the Examples 1-2 can optionally include wherein the dielectric includes at least one member selected from the group comprising: N—H, Si—H, and Si—O—Si groups.

Presence of N—H, Si—H, and Si—O—Si groups may be indicative of polyorganosilazanes being used in block 101 of FIG. 1.

In example 4 the subject matter of the Examples 1-3 can optionally include wherein the dielectric is crosslinked with at least one member selected from the group comprising oxygen, nitrogen, and ammonia.

Example 5 include a semiconductor apparatus comprising: a substrate including a trench with an aspect ratio of at least 5:1 (height:width) and a critical dimension no greater than 15 nm; and a dielectric substantially filling the trench; wherein (a) the dielectric includes a material selected from the group comprising silicon nitride and silicon carbide; and (b) the material is non-stoichiometric and includes less than 8% oxygen.

In example 6 the subject matter of the Example 5 can optionally include wherein the material includes silicon nitride.

In another version of example 6 the subject matter of the Example 5 can optionally include wherein the material includes silicon carbide.

In example 7 the subject matter of the Examples 5-6 can optionally include wherein the material is doped with carbon.

In example 8 the subject matter of the Examples 5-7 can optionally include wherein the material includes a carbon-carbon double bond.

In example 9 the subject matter of the Examples 5-8 can optionally include wherein the material includes N—H, Si—H, and Si—O—Si groups.

In example 10 the subject matter of the Examples 5-9 can optionally include wherein the material is crosslinked with at least one member selected from the group comprising oxygen, nitrogen, and ammonia.

In example 11 the subject matter of the Examples 5-10 can optionally include wherein the dielectric is included in a film that is profile-insensitive.

For example, use of a flowable dielectric is non-conformal and therefore fills from the bottom up without regard to, for example, the width of a trench.

In example 12 the subject matter of the Examples 5-11 can optionally include wherein the dielectric is included in a film that is non-conformal.

Non-flowable CVD and ALD are conformal.

In example 13 the subject matter of the Examples 5-12 can optionally include wherein the dielectric is not a non-flowable chemical vapor deposition (CVD) dielectric or an atomic layer deposition (ALD) dielectric.

In example 14 the subject matter of the Examples 5-13 can optionally include wherein the dielectric is formed using a vapor phase precursor.

In example 15 the subject matter of the Examples 5-14 can optionally include wherein the dielectric is not an oxide.

For example, the dielectric includes no oxide.

In example 16 the subject matter of the Examples 5-15 can optionally include wherein the dielectric is not a spin-on dielectric (SOD).

A SOD by nature is exposed to oxygen, which would then be included in the SOD making the SOD more susceptible to etching (which leads to voids).

In example 17 the subject matter of the Examples 5-16 can optionally include wherein the trench is included between two adjacent semiconductor fins.

Example 18 includes depositing flowable dielectric precursor into a trench having an aspect ratio of at least 5:1 (height:width) to form a pre-ceramic network, wherein the flowable dielectric precursor includes at least one of an oligomeric dielectric precursor and a polymeric dielectric precursor and is generated from a vapor phase precursor; crosslinking the pre-ceramic network to form a crosslinked pre-ceramic polymeric network; and annealing the crosslinked pre-ceramic polymeric network to further crosslink and harden the crosslinked pre-ceramic polymeric network into an amorphous ceramic dielectric.

In example 19 the subject matter of the Examples 18 can optionally include depositing the flowable dielectric, crosslinking the pre-ceramic network, and annealing the crosslinked preceramic polymeric network all at less than 500 degrees Celsius.

In example 20 the subject matter of the Examples 18-19 can optionally include wherein the vapor phase precursor includes at least one silazane compound.

Other embodiments may include amino-silane precursors.

In example 21 the subject matter of the Examples 18-20 can optionally include wherein the vapor phase precursor includes at least one member selected from the group comprising Trisilylamine (TSA), cyclodisilazane, Bis(tertiary-butyl-amino)silane (BTBAS), Tris(isopropylamino)silane (TIPAS), Bis(diethylamino)ethylsilane (BDEAES), Bis(diethylamino)silane (BDEAS), Tris(ethylamino)silane (TEAS), polycarbosilanes, polyvinylsilanes, and mixtures thereof.

In example 22 the subject matter of the Examples 18-21 can optionally include wherein crosslinking the pre-ceramic network includes adding nitrogen to the pre-ceramic network.

In example 23 the subject matter of the Examples 18-22 can optionally include depositing the flowable dielectric precursor under vacuum and then, without breaking the vacuum, crosslinking the pre-ceramic network under the vacuum.

For example, blocks 101 and 102 may be done without breaking the vacuum. The vacuum may be broken in between blocks 102 and 103.

In example 24 the subject matter of the Examples 18-23 can optionally include wherein depositing the flowable dielectric precursor into the trench comprises catalyzing formation of the pre-ceramic network with ammonia.

Ammonia includes, for example, radicals of ammonia.

In example 25 the subject matter of the Examples 18-24 can optionally include wherein the crosslinking the pre-ceramic network includes crosslinking at least one of terminal hydrides of the pre-ceramic network and amines of the pre-ceramic network.

The foregoing description of the embodiments of the invention has been presented for the purposes of illustration and description. It is not intended to be exhaustive or to limit the invention to the precise forms disclosed. This description and the claims following include terms, such as left, right, top, bottom, over, under, upper, lower, first, second, etc. that are used for descriptive purposes only and are not to be construed as limiting. For example, terms designating relative vertical position refer to a situation where a device side (or active surface) of a substrate or integrated circuit is the “top” surface of that substrate; the substrate may actually be in any orientation so that a “top” side of a substrate may be lower than the “bottom” side in a standard terrestrial frame of reference and still fall within the meaning of the term “top.” The term “on” as used herein (including in the claims) does not indicate that a first layer “on” a second layer is directly on and in immediate contact with the second layer unless such is specifically stated; there may be a third layer or other structure between the first layer and the second layer on the first layer. The embodiments of a device or article described herein can be manufactured, used, or shipped in a number of positions and orientations. Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

What is claimed is:

1. A semiconductor apparatus comprising:
a trench with an aspect ratio of at least 7:1 (height:width); and
a dielectric included in the trench;
wherein the dielectric: (a) includes carbon and at least one of silicon nitride and silicon carbide, and (b) does not include an oxide.

2. The apparatus of claim 1, wherein the dielectric includes a carbon-carbon double bond.

3. The apparatus of claim 1, wherein the dielectric includes at least one member selected from the group comprising: N—H, Si—H, and Si—O—Si groups.

4. The apparatus of claim 1, wherein the dielectric is crosslinked with at least one member selected from the group comprising oxygen, nitrogen, and ammonia.

5. A semiconductor apparatus comprising:
a substrate including a trench with an aspect ratio of at least 5:1 (height:width) and a critical dimension no greater than 15 nm; and
a dielectric substantially filling the trench;
wherein (a) the dielectric includes a material selected from the group comprising silicon nitride and silicon carbide; and (b) the material is non-stoichiometric and includes less than 8% oxygen.

6. The apparatus of claim 5, wherein the material includes silicon nitride.

7. The apparatus of claim 5, wherein the material is doped with carbon.

8. The apparatus of claim 7, wherein the material includes a carbon-carbon double bond.

9. The apparatus of claim 7, wherein the material includes N—H, Si—H, and Si—O—Si groups.

10. The apparatus of claim 5, wherein the material is crosslinked with at least one member selected from the group comprising oxygen, nitrogen, and ammonia.

11. The apparatus of claim 5, wherein the dielectric is included in a film that is profile-insensitive.

12. The apparatus of claim 5, wherein the dielectric is included in a film that is non-conformal.

13. The apparatus of claim 12, wherein the dielectric is not a non-flowable chemical vapor deposition (CVD) dielectric or an atomic layer deposition (ALD) dielectric.

14. The apparatus of claim 13, wherein the dielectric is formed using a vapor phase precursor.

15. The apparatus of claim 5, wherein the dielectric is not an oxide.

16. The apparatus of claim 15, wherein the dielectric is not a spin-on dielectric (SOD).

17. The apparatus of claim 5, wherein the trench is included between two adjacent semiconductor fins.

18. A method comprising:
depositing flowable dielectric precursor into a trench having an aspect ratio of at least 5:1 (height:width) to form a pre-ceramic network, wherein the flowable dielectric precursor includes at least one of an oligomeric dielectric precursor and a polymeric dielectric precursor and is generated from a vapor phase precursor;
crosslinking the pre-ceramic network to form a crosslinked pre-ceramic polymeric network; and
annealing the crosslinked pre-ceramic polymeric network to further crosslink and harden the crosslinked pre-ceramic polymeric network into an amorphous ceramic dielectric.

19. The method of claim 18 comprising depositing the flowable dielectric, crosslinking the pre-ceramic network, and annealing the crosslinked preceramic polymeric network all at less than 500 degrees Celsius.

20. The method of claim 19, wherein the vapor phase precursor includes at least one silazane compound.

21. The method of claim 19, wherein the vapor phase precursor includes at least one member selected from the group comprising Trisilylamine (TSA), cyclodisilazane, Bis(tertiary-butyl-amino)silane (BTBAS), Tris(isopropylamino)silane (TIPAS), Bis(diethylamino)ethylsilane (BDEAES), Bis(diethylamino)silane (BDEAS), Tris(ethylamino)silane (TEAS), polycarbosilanes, polyvinylsilanes, and mixtures thereof.

22. The method of claim 18, wherein crosslinking the pre-ceramic network includes adding nitrogen to the pre-ceramic network.

23. The method of claim 18 comprising depositing the flowable dielectric precursor under vacuum and then, without breaking the vacuum, crosslinking the pre-ceramic network under the vacuum.

24. The method of claim 23, wherein depositing the flowable dielectric precursor into the trench comprises catalyzing formation of the pre-ceramic network with ammonia.

25. The method of claim 19, wherein the crosslinking the pre-ceramic network includes crosslinking at least one of terminal hydrides of the pre-ceramic network and amines of the pre-ceramic network.
